(19) United States
(12) Patent Application Publication
(10) Pub. No.: US 2025/0140579 A1
(43) Pub. Date: May 1, 2025

(54) SPIN CHUCK AND WAFER CLEANING DEVICE INCLUDING THE SAME

(71) Applicant: SAMSUNG ELECTRONICS CO., LTD., Suwon-si (KR)

(72) Inventors: Sunghwan Kim, Suwon-si (KR); Kyungwon Kang, Suwon-si (KR); Dongwook Kim, Suwon-si (KR); Seok Heo, Suwon-si (KR)

(21) Appl. No.: 18/737,254

(22) Filed: Jun. 7, 2024

(30) Foreign Application Priority Data
Oct. 26, 2023 (KR) 10-2023-0145091

(51) Int. Cl. H01L 21/67; H01L 21/683

(52) U.S. Cl. CPC H01L 21/67051; H01L 21/67103; H01L 21/67109; H01L 21/6838

(57) ABSTRACT

Provided are a wafer cleaning device and a method of optimizing the same. The wafer cleaning device includes an upper nozzle configured to spray a cleaning solution onto a front surface of a wafer, a spin chuck provided below the wafer to rotate the wafer and configured to heat a central region of the wafer, and a plurality of lower nozzles provided below the wafer to spray a temperature control liquid having a higher temperature than the cleaning solution onto a rear surface of the wafer, the plurality of lower nozzles configured to heat an outer region of the wafer that surrounds the central region of the wafer. A temperature gradient formed by the spin chuck and the plurality of lower nozzles causes a cleaning solution to flow in a cleaning solution layer on the front surface of the wafer.

### CROSS-REFERENCE TO RELATED APPLICATION

This application claims priority under 35 U.S.C. § 119 to Korean Patent Application No. 10-2023-0145091, filed on Oct. 26, 2023, in the Korean Intellectual Property Office, the disclosure of which is incorporated by reference herein in its entirety.

### BACKGROUND

With the development of electronics technology, semiconductor devices have recently been rapidly down-scaled. In particular, during wet cleaning processes while the semiconductor devices are manufactured, particles may not be completely removed by rinsing processes due to the down-scaling of the semiconductor devices, which causes defects in wafers, reduces productivity, and increases the amount of cleaning solution to be used. Accordingly, there is a need to develop technology to efficiently remove the particles.

### SUMMARY

The present disclosure provides a spin chuck capable of forming a temperature gradient of a cleaning solution and a wafer cleaning device including the same.

According to an aspect of the present disclosure, there is provided a wafer cleaning device including an upper nozzle configured to spray a cleaning solution onto a front surface of a wafer, a spin chuck provided below the wafer to rotate the wafer and configured to heat a central region of the wafer, and a plurality of lower nozzles provided below the wafer to spray a temperature control liquid having a higher temperature than the cleaning solution onto a rear surface of the wafer, the plurality of lower nozzles configured to heat an outer region of the wafer that surrounds the central region of the wafer, wherein a temperature gradient formed by the spin chuck and the plurality of lower nozzles causes a cleaning solution layer including the cleaning solution to flow on the front surface of the wafer.

According to another aspect of the present disclosure, there is provided a wafer cleaning device including an upper nozzle configured to spray a cleaning solution onto a front surface of a wafer, a spin chuck provided below the wafer to rotate the wafer and configured to heat a central region of the wafer, a plurality of lower nozzles provided below the wafer to spray a temperature control liquid onto a rear surface of the wafer and configured to heat an outer region of the wafer, and a power transmission structure provided below the wafer, spaced apart from the spin chuck, and surrounding the spin chuck, wherein the power transmission structure includes a plurality of power transmitters that wirelessly transmit power, and the spin chuck includes a plurality of power receivers configured to wirelessly receive the power from the plurality of power transmitters, a plurality of thermoelectric elements configured to convert the power received from the plurality of power receivers into heat, and a plurality of heat transfer structures configured to transfer the heat generated by the plurality of thermoelectric elements to the central region of the wafer, the heat transfer structures heating the central region of the wafer to different temperatures, wherein the spin chuck and the plurality of lower nozzles cause a cleaning solution layer including the cleaning solution sprayed from the upper nozzle to flow on the front surface of the wafer.

According to another aspect of the present disclosure, there is provided a wafer cleaning device including a cleaning chamber, a spin chuck located in a lower portion of the cleaning chamber, an upper nozzle disposed in an upper portion of the cleaning chamber and configured to spray a cleaning solution, a power transmission structure spaced apart from the spin chuck and surrounding the spin chuck, and a plurality of lower nozzles spaced apart from the power transmission structure and configured to spray a temperature control liquid, wherein the power transmission structure includes a power transmitter that transmits power, and the spin chuck includes a power receiver configured to receive the power from the power transmitter, a thermoelectric element configured to convert the power received from the power receiver into heat, a heat transfer structure connected to the thermoelectric element and configured to transfer the heat generated from the thermoelectric element, and a vacuum hole, wherein the spin chuck and the plurality of lower nozzles provide an environment in which a thermophoresis effect or Marangoni convection is formed.

### BRIEF DESCRIPTION OF THE DRAWINGS

Implementations will be more clearly understood from the following detailed description taken in conjunction with the accompanying drawings in which:

FIG. 1 is a diagram illustrating an example wafer cleaning device;

FIG. 2 is a cross-sectional view showing an example wafer cleaning device;

FIG. 3A is a layout showing a partial configuration of an example wafer cleaning device;

FIG. 3B is a layout showing a partial configuration of the wafer cleaning device at another vertical level;

FIG. 3C is a layout showing a partial configuration of the wafer cleaning device at another vertical level;

FIG. 4 is a layout showing an example wafer cleaning device;

FIG. 5A is a cross-sectional view showing an operation process of the wafer cleaning device;

FIG. 5B is an enlarged view of FIG. 5A;

FIG. 6 is a layout showing the operation process of the wafer cleaning device; and

FIG. 7 is a diagram showing a heating temperature optimization process of the wafer cleaning device.

### DETAILED DESCRIPTION

Advantages and features of the present disclosure and implementation methods thereof will be clarified through following implementations described in detail with reference to the accompanying drawings. The present disclosure may, however, be embodied in different forms and should not be construed as limited to the implementations set forth herein. Rather, these implementations are provided so that this disclosure will be thorough and complete, and will fully convey the scope to those skilled in the art. The relative sizes of layers and regions in the drawings may be exaggerated for clarity of description.

When one element is referred to as being “connected to” or “coupled to” another element, the one element can be directly connected or coupled to another element or indirectly connected or coupled to another element with an intervening element therebetween. On the other hand, when one element is referred to as being “directly connected to” or “directly coupled to” another element, there is no intervening element.

When an element or layer is referred to as being “above” or “on” another element or layer, the element or the layer can be directly on another element or layer, or an intervening element or layer may also be present therebetween. On the other hand, when an element is referred to as being “directly on” or “directly above,” there is no intervening element or layer.

Although terms, such as first and second, are used to describe various elements, components, and/or sections, these elements, components, and/or sections are not limited by these terms. These terms are merely used to distinguish one element, component, or section from other elements, elements, or sections. Therefore, a first element, a first component, or a first section described below may also be referred to as a second element, a second component, or a second section within the present disclosure.

The terms described herein are used only to explain implementations while not being limiting. In this specification, the singular forms include the plural forms as well, unless the context clearly indicates otherwise.

Hereinafter, implementations are described in detail with reference to the accompanying drawings. The same reference numerals are given to the same elements in the drawings, and repeated descriptions thereof are omitted.

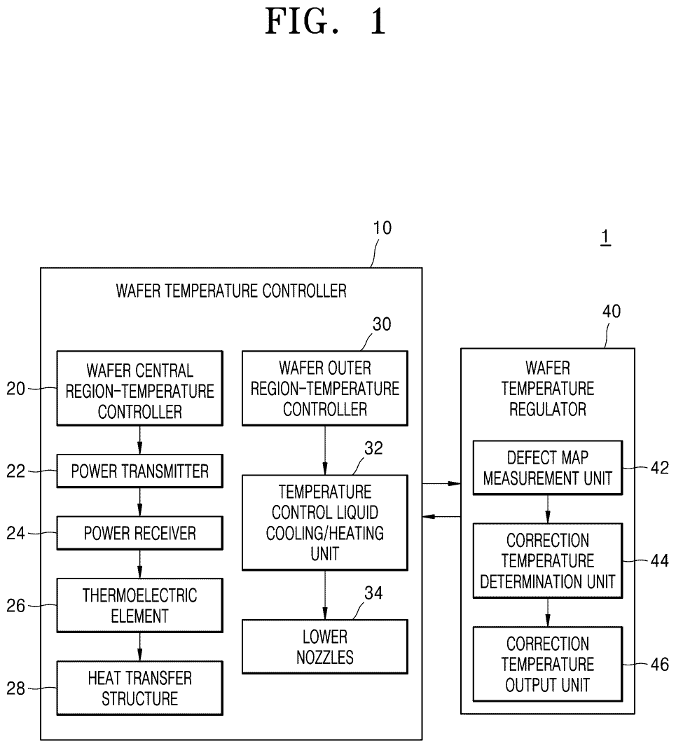

FIG. 1 is a diagram illustrating an example wafer cleaning system 1 including a wafer cleaning device.

Referring to FIG. 1, the wafer cleaning system 1 may include a wafer temperature controller 10 and a wafer temperature regulator 40 for obtaining a temperature that is optimized to remove particles from a wafer. In this specification, “particles” may refer to impurity particles that cause defects in the wafer. The wafer temperature controller 10 may include a wafer central region-temperature controller 20 for controlling the temperature of the central region of the wafer and a wafer outer region-temperature controller 30 for controlling the temperature of the outer region of the wafer other than the central region of the wafer. The wafer central region-temperature controller 20 may input, to a power transmitter 22, a target temperature of a central region of a wafer (hereinafter, referred to as a wafer central region), which is to be achieved by heating the wafer central region. The wafer outer region-temperature controller 30 may input, to a temperature control liquid cooling/heating unit 32, a target temperature of an outer region of a wafer (hereinafter, referred to as a wafer outer region), which is to be achieved by heating the wafer outer region. Also, the wafer temperature controller 10 may include the power transmitter 22 that transmits corresponding power to a power receiver 24 to achieve the target temperature input from the wafer central region-temperature controller 20, the power receiver 24 that receives the power from the power transmitter 22, a thermoelectric element 26 that converts the power received by the power receiver 24 into heat, and a heat transfer structure 28 that transfers the heat generated by the thermoelectric element 26 to the wafer. In addition, the wafer temperature controller 10 may include a temperature control liquid cooling/heating unit 32 that adjusts the temperature of a cleaning solution sprayed from a plurality of lower nozzles 34 to achieve the target temperature input from the wafer outer region-temperature controller 30 and the plurality of lower nozzles 34 that spray a cleaning solution having the temperature adjusted by the temperature control liquid cooling/heating unit 32 onto the wafer.

The wafer temperature regulator 40 may include a defect map measurement unit 42 that measures a defect map of the wafer on which a cleaning process has been performed by the wafer temperature controller 10, a correction temperature determination unit 44 that determines whether to correct the target temperature of the wafer temperature controller 10 on the basis of the defect map of the wafer, and a correction temperature output unit 46 that outputs the corrected target temperature and transmits the same to the wafer temperature controller 10.

Through interaction with the wafer temperature regulator 40, the wafer temperature controller 10 may control the temperature of the central region of the wafer and the temperature of the outer region of the wafer so as to minimize defects on the wafer.

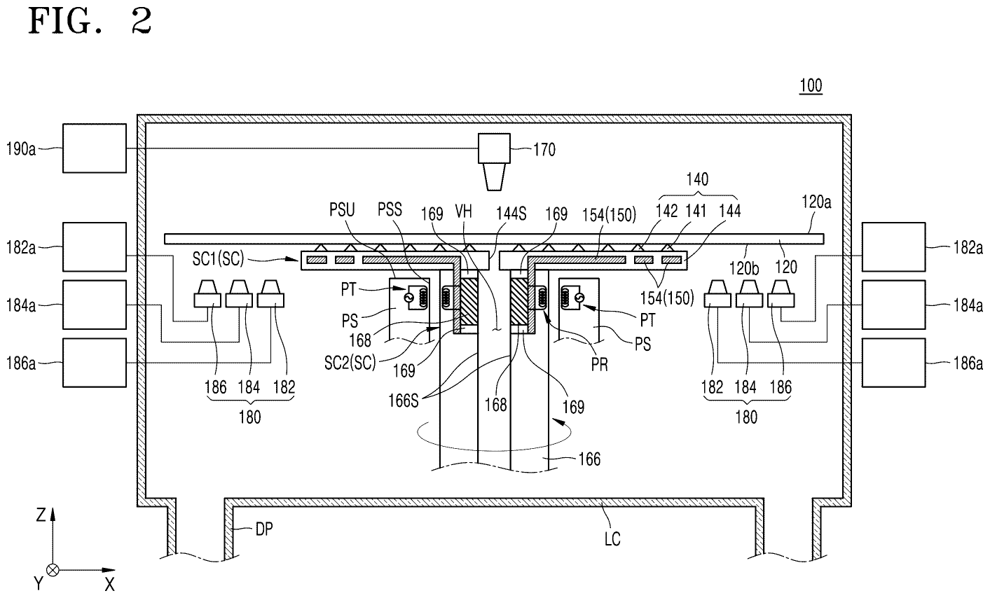

FIG. 2 is a cross-sectional view showing an example wafer cleaning device 100.

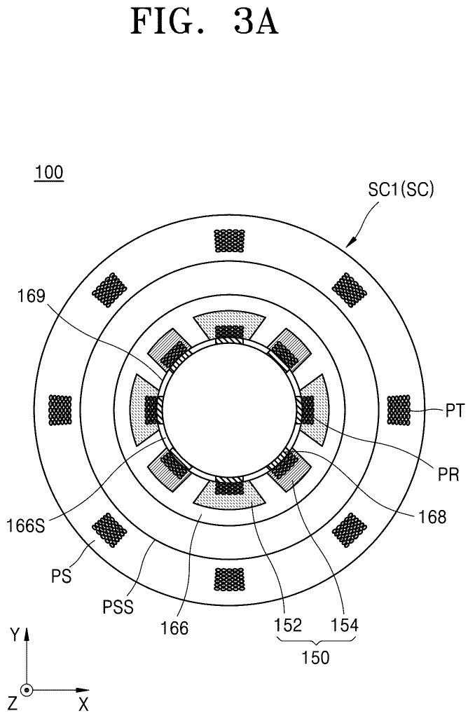

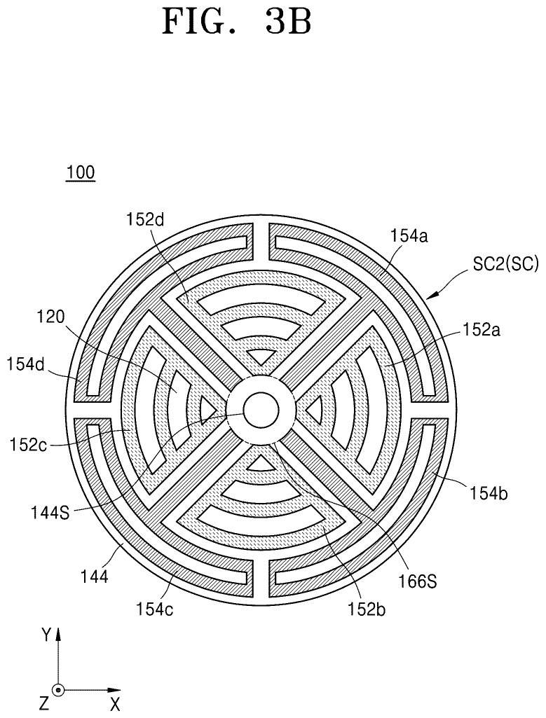

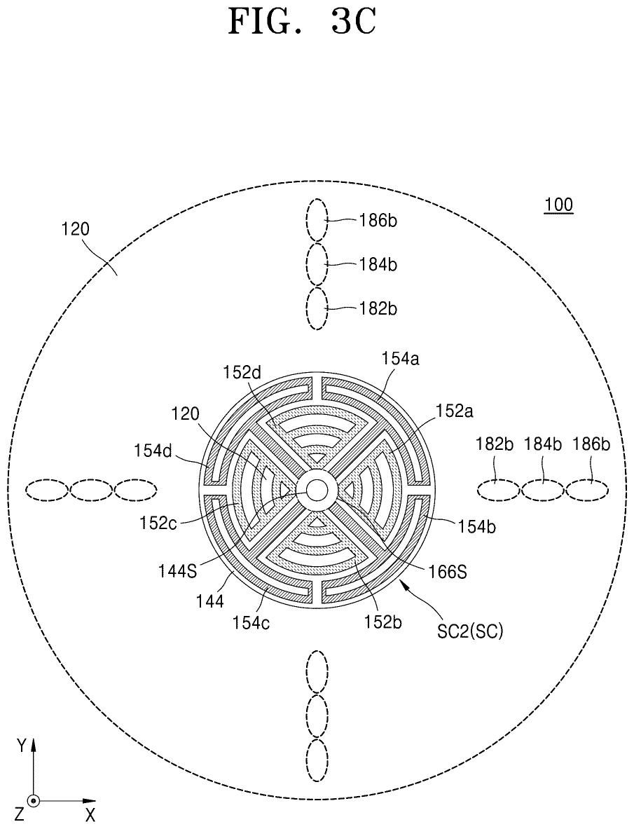

FIG. 3A is a layout showing a partial configuration of the wafer cleaning device 100.

FIG. 3B is a layout showing a partial configuration of the wafer cleaning device 100 at another vertical level.

FIG. 3C is a layout showing a partial configuration of the wafer cleaning device 100 at another vertical level.

Referring to FIG. 2, the wafer cleaning device 100 may include a single wafer-type substrate cleaning device in which pressure is applied to the surface of a wafer 120 by droplets of the cleaning solution provided to the wafer 120, thereby removing particles from the surface of the wafer 120.

The wafer cleaning device 100 may include a cleaning chamber LC, a spin chuck SC that holds and rotates the wafer 120, a power transmission structure PS that surrounds the lower portion of the spin chuck SC, an upper nozzle 170 that provides a cleaning solution to a front surface 120a of the wafer 120, and a plurality of lower nozzles 180 that provide a temperature control liquid to a rear surface 120b of the wafer 120. The spin chuck SC, the power transmission structure PS, the upper nozzle 170, and the plurality of lower nozzles 180 may be arranged in the inner space of the cleaning chamber LC. Specifically, the upper nozzle 170 may be located in the upper portion the cleaning chamber LC and the spin chuck SC, the power transmission structure PS, and the plurality of lower nozzles 180 may be arranged in the lower portion of the cleaning chamber LC.

In implementations, the cleaning chamber LC may include a discharge pipe DP that is located at the bottom of the cleaning chamber LC. The discharge pipe DP may discharge, to the outside of the cleaning chamber LC, the cleaning solution and the temperature control liquid which have been used in the cleaning process. In this specification, the “cleaning solution” may also be referred to as a rinse solution and include deionized (DI) water, carbonated water, electrolytically ionized water, hydrogen water, ozone water, or diluted hydrochloric acid aqueous solution. The cleaning solution may be provided before or after the cleaning process of the wafer 120. In implementations, the temperature control liquid may include the same material as the cleaning solution.

As illustrated in FIG. 2, the spin chuck SC may mount the wafer 120 in a horizontal state. The spin chuck SC may rotate clockwise or counterclockwise, and the wafer 120 mounted on the spin chuck SC may rotate clockwise or counterclockwise about the central axis of the spin chuck SC. Particles may escape from the wafer 120 together with the cleaning solution due to centrifugal force caused by rotation of the wafer 120.

The spin chuck SC may include a vacuum chuck for vacuum-suctioning the wafer 120 so as to fix the wafer 120 and may have a vacuum hole VH. The spin chuck SC may include an upper spin chuck SC1 and a lower spin chuck SC2 disposed below the upper spin chuck SC1 and extending from the upper spin chuck SC1 in a vertical direction Z. The term “vertical level” used herein refers to the distance from the front surface 120a of the wafer 120 in the vertical direction (Z-direction or (−)Z-direction). In implementations, the upper spin chuck SC1 may be designed to have a disc shape similar to the wafer 120 and the lower spin chuck SC2 may be designed to have a cylinder shape.

The upper spin chuck SC1 may include an upper plate 140 fixing the wafer 120 and a heat transfer structure 150 located inside the upper plate 140. The upper plate 140 may be placed such that the upper surface of the upper plate 140 faces the rear surface 120b of the wafer 120. The width of the upper plate 140 in a first horizontal direction X may be less than the width of the wafer 120 in the first horizontal direction X, but implementations are not limited thereto. For example, the width of the upper plate 140 in the first horizontal direction X may be greater than the width of the wafer 120 in the first horizontal direction X.

The upper plate 140 may include an outer pin 141 and a plurality of inner pins 142 for fixing the wafer 120 and a support upper plate 144 for supporting the outer pin 141 and the plurality of inner pins 142. The outer pin 141 and the plurality of inner pins 142 may be arranged between the wafer 120 and the support upper plate 144 and prevent the wafer 120 from escaping from the support upper plate 144 during a cleaning process. The outer pin 141 and the plurality of inner pins 142 may be arranged on the support upper plate 144 and hold the wafer 120 such that the front surface 120a of the wafer 120 faces up and the rear surface 120b of the wafer 120 faces down. The outer pin 141 and the plurality of inner pins 142 protrude from the support upper plate 144, and thus, a gap may exist between the wafer 120 and the support upper plate 144.

In order to support the wafer 120 on the outer pin 141 and the plurality of inner pins 142, the gap between the wafer 120 and the support upper plate 144 may be connected to the vacuum hole VH. The vacuum hole VH may include a portion connected to (e.g. in contact with) an inner wall 144S of the support upper plate 144 and a portion connected to (e.g. in contact with) an inner wall 166S of a lower plate 166. The horizontal width of the portion of the vacuum hole VH connected to (e.g. in contact with) the inner wall 144S of the support upper plate 144 may be less than the horizontal width of the portion of the vacuum hole VH connected to (e.g. in contact with) the inner wall 166S of the lower plate 166.

A vacuum line may be connected to the vacuum hole VH to maintain a vacuum state in the vacuum hole VH. The vacuum hole VH may be located inside the lower spin chuck SC2 as shown in the drawing, but implementations are not limited thereto. Irrespective of the lower spin chuck SC2, the vacuum hole VH may be provided to directly maintain the gap between the wafer 120 and the support upper plate 144 in a vacuum state.

In implementations, the outer pin 141 may surround the plurality of inner pins 142 so as to maintain a state in which the wafer 120 is fixed. In other words, the outer pin 141 may have a cylindrical shape extending along the outside of the support upper plate 144, and the plurality of inner pins 142 may be arranged in the inner space of the outer pin 141. The inner space of the outer pin 141 may be maintained in a vacuum state.

The lower spin chuck SC2 may include a lower plate 166, a heat transfer structure 150 that extends from the inside of the support upper plate 144 into the lower plate 166, a thermoelectric element 168 connected to (e.g. in contact with) the heat transfer structure 150, a heat insulating member 169 that separates the thermoelectric element 168 from the support upper plate 144 and the lower plate 166, and a power receiver PR that transfers power to the thermoelectric element 168. In implementations, the heat transfer structure 150, the thermoelectric element 168, the heat insulating member 169, and the power receiver PR may be arranged on the lower plate 166.

The thermoelectric element 168 may receive the power from the power receiver PR and convert the received power into heat, and the heat transfer structure 150 may receive the heat from the thermoelectric element 168 and heat the wafer 120.

As illustrated in FIGS. 2, 3A, and 3B, the heat transfer structure 150 may be arranged inside the support upper plate 144 and parallel with the rear surface 120b of the wafer 120. The heat transfer structure 150 may bend at a portion of the support upper plate 144, overlapping with the lower plate 166 in the vertical direction Z, and extend into the lower plate 166.

As illustrated in FIGS. 3A and 3B, the heat transfer structure 150 may include a plurality of inner heat transfer structures 152 and a plurality of outer heat transfer structures 154. The plurality of inner heat transfer structures 152 and the plurality of outer heat transfer structures 154 may be spaced apart from each other. For example, a first inner heat transfer structure 152a, a second inner heat transfer structure 152b, a third inner heat transfer structure 152c, and a fourth inner heat transfer structure 152d may be arranged along the inner wall 166S of the lower plate 166 and spaced apart from each other with portions of the support upper plate 144 therebetween. A first outer heat transfer structure 154a, a second outer heat transfer structure 154b, a third outer heat transfer structure 154c, and a fourth outer heat transfer structure 154d may be arranged along the inner wall 166S of the lower plate 166 and spaced apart from each other with portions of the support upper plate 144 therebetween. The portions of the support upper plate 144 may be spaced apart from each other and respectively arranged between the first inner heat transfer structure 152a and the first outer heat transfer structure 154a, between the second inner heat transfer structure 152b and the second outer heat transfer structure 154b, between the third inner heat transfer structure 152c and the third outer heat transfer structure 154c, and between the fourth inner heat transfer structure 152d and the fourth outer heat transfer structure 154d.

Accordingly, the plurality of inner heat transfer structures 152 and the plurality of outer heat transfer structures 154 may independently heat the central region of the wafer 120. The plurality of inner heat transfer structures 152 and the plurality of outer heat transfer structures 154 may heat the central region of the wafer 120 at different target temperatures which are output from the wafer temperature regulator 40 shown in FIG. 1.

As illustrated in FIG. 3B, each of the plurality of inner heat transfer structures 152 and the plurality of outer heat transfer structures 154 may include a plurality of arc-shaped pipes and a plurality of straight pipes. For example, the plurality of inner heat transfer structures 152 may each include three arc-shaped pipes, a straight pipe connecting ends of the arc-shaped pipes to each other, and another straight pipe connecting the other ends opposite to the ends of the arc-shaped pipes. For example, the plurality of outer heat transfer structures 154 may each include two arc-shaped pipes, a straight pipe connecting ends of the arc-shaped pipes to each other, and another straight pipe connecting the other ends opposite to the ends of the arc-shaped pipes. The plurality of outer heat transfer structures 154 may each further include another straight pipe extending between the plurality of inner heat transfer structures 152.

In implementations, the heat transfer structure 150 may include a heat pipe. For example, the heat pipe may include metals having good thermal conductivity, such as copper and aluminum, and the fluid operating inside the heat pipe may include ammonia, alcohol, methanol, or water in a liquid state at room temperature.

As illustrated in FIGS. 2 and 3A, the heat transfer structure 150 may be connected to (e.g. in contact with) the thermoelectric element 168. As used herein, the thermoelectric element 168 may also be referred to as a Peltier element. The thermoelectric element 168 may generate heat by the Peltier effect. Specifically, heat generation may occur when current is applied to the thermoelectric element 168 by the power receiver PR. The generated heat may be transferred to the heat transfer structure 150 via the contact surface between the heat transfer structure 150 and the thermoelectric element 168.

In implementations, the upper surface and lower surface of the thermoelectric element 168 may be covered by the heat insulating member 169, the inner wall of the thermoelectric element 168 may be exposed via the vacuum hole VH, and the outer wall of the thermoelectric element 168 may be covered by the heat transfer structure 150. The thermoelectric element 168 may be spaced apart from the upper plate 140 and the lower plate 166 with the heat insulating member 169 therebetween.

The heat insulating member 169 may prevent heat emitted from the thermoelectric element 168 from being transferred to the upper plate 140 and the lower plate 166. The heat insulating member 169 may be located between the thermoelectric element 168 and the upper plate 140 and between the thermoelectric element 168 and the lower plate 166. The heat insulating member 169 may include a heat-resistant material. The thermoelectric element 168 may be connected to the power receiver PR and may receive the power from a power transmitter PT via the power receiver PR.

As illustrated in FIG. 3A, the thermoelectric element 168 may be provided in plurality. The plurality of thermoelectric elements 168 may be spaced apart from each other with the heat insulating member 169 therebetween, and each of the plurality of thermoelectric elements 168 may be connected to a corresponding power receiver PR among a plurality of power receivers PR. The heat insulating member 169 may prevent heat from being transferred from a selected thermoelectric element from among the plurality of thermoelectric elements 168 to another thermoelectric element 168 adjacent to the selected one from among the plurality the thermoelectric elements 168. The heat insulating member 169 may be located between the plurality of thermoelectric elements 168.

Also, each of the plurality of thermoelectric elements 168 may be thermally connected to a corresponding heat transfer structure 150 among a plurality of heat transfer structures 150. For example, two first thermoelectric elements facing each other in the first horizontal direction X, two second thermoelectric elements facing each other in the second horizontal direction Y, and four third thermoelectric elements arranged diagonally between the first thermoelectric elements and the second thermoelectric elements may be placed inside the lower plate 166. Here, the two first thermoelectric elements and the two second thermoelectric elements may be connected to the inner heat transfer structures 152, and the four third thermoelectric elements may be connected to the outer heat transfer structures 154. Accordingly, the plurality of thermoelectric elements 168 may be driven independently of each other, and the plurality of thermoelectric elements 168 may emit heat of different intensities. For example, the plurality of thermoelectric elements 168 may receive different amounts of power and then heat the plurality of inner heat transfer structures 152 and the plurality of outer heat transfer structures 154 to different temperatures.

As illustrated in FIGS. 2 and 3A, in order to apply current to the plurality of thermoelectric elements 168, the wafer cleaning device 100 may include the power receiver PR located inside the spin chuck SC and the power transmission structure PS spaced apart from the spin chuck SC. The power transmission structure PS may include the power transmitter PT. The power transmitter PT may wirelessly transmit power to the power receiver PR. For example, the power transmitter PT and the power receiver PR may each include an electromagnetic coil panel. In implementations, the power transmitter PT may include a transmitter coil, and the power receiver PR may include a receiver coil. The receiver coil may receive the power wirelessly from the transmitter coil by an electromagnetic induction or resonance method. The transmitter coil may wirelessly transmit the power to the receiver coil by the electromagnetic induction or resonance method.

In implementations, the power transmitter PT may receive a target temperature value of the wafer 120 from the wafer central region-temperature controller 20 illustrated in FIG. 1, and the power required to achieve the target temperature may be transmitted from the power transmitter PT to the power receiver PR. Subsequently, the heat required to achieve the target temperature may be generated in the thermoelectric element 168. This heat may be transferred to the central region of the wafer 120 via the heat transfer structure 150, thereby heating the central region of the wafer 120 to the target temperature.

The power transmission structure PS may be configured to support the power transmitter PT. The power transmission structure PS may be spaced apart from the upper spin chuck SC1 in the vertical direction Z. Also, the power transmission structure PS may be spaced apart from the lower spin chuck SC2 in the first horizontal direction X and the second horizontal direction Y and may surround the outer wall of the lower spin chuck SC2. Specifically, an upper surface PSU of the power transmission structure PS may be spaced apart from the lower surface of the upper spin chuck SC1. An inner wall PSS of the power transmission structure PS may be spaced apart from the outer wall of the lower spin chuck SC2. For example, the power transmission structure PS may have a cylindrical shape, and the lower spin chuck SC2 may be located in the inner space of the power transmission structure PS. The power transmission structure PS and the spin chuck SC are spaced apart from each other, and thus, friction between the power transmission structure PS and the spin chuck SC may be prevented from occurring.

As illustrated in FIG. 2, the wafer cleaning device 100 may include the upper nozzle 170 and the plurality of lower nozzles 180. The upper nozzle 170 may face the front surface 120a of the wafer 120, and the plurality of lower nozzles 180 may face the rear surface 120b of the wafer 120. The plurality of lower nozzles 180 may be arranged symmetrically to each other about the spin chuck SC. The upper nozzle 170 may spray a cleaning solution onto the front surface 120a of the wafer 120 and the plurality of lower nozzles 180 may spray a temperature control liquid onto the rear surface 120b of the wafer 120. The upper nozzle 170 may be connected to a supply source 190a via a supply pipe.

In implementations, the upper nozzle 170 may be fixed in the cleaning chamber LC. Also, in some implementations, an upper nozzle 170 may be moved above the wafer 120 by a nozzle arm.

Each of the plurality of lower nozzles 180 may be connected to a corresponding one of a plurality of supply sources 182a, 184a, and 186a via a supply pipe. Each of the plurality of supply sources 182a, 184a, and 186a may be connected to the temperature control liquid cooling/heating unit 32 of FIG. 1 and may be connected to the wafer outer region-temperature controller 30 via the temperature control liquid cooling/heating unit 32. The target temperature value of the outer region of the wafer 120 may be transmitted via the wafer outer region-temperature controller 30 illustrated in FIG. 1, and the temperature control liquid cooling/heating unit 32 may cool or heat the temperature control liquid so as to achieve the target temperature. Subsequently, the plurality of lower nozzles 180 may spray the temperature control liquid onto the rear surface 120b of the wafer 120, and thus, the outer region of the wafer 120 may be heated to the target temperature.

In implementations, the plurality of lower nozzles 180 may be fixed in the cleaning chamber LC. Also, in some implementations, a plurality of lower nozzles 180 may be moved below the wafer 120 by a nozzle arm.

In implementations, the plurality of lower nozzles 180 may spray temperature control liquids having different temperatures. For example, a first lower nozzle 182 may spray a first temperature control liquid having a first temperature, a second lower nozzle 184 may spray a second temperature control liquid having a second temperature, and a third lower nozzle 186 may spray a third temperature control liquid having a third temperature. In implementations, a lower nozzle adjacent to the outer region of the wafer 120 among the plurality of lower nozzles 180 may spray a temperature control liquid having a lower temperature than a lower nozzle adjacent to the central region of the wafer 120 among the plurality of lower nozzles 180. For example, the first temperature control liquid may have a higher temperature than the second temperature control liquid, and the second temperature control liquid may have a higher temperature than the third temperature control liquid. The cleaning solution sprayed by the upper nozzle 170 may have a temperature lower than temperatures of the temperature control liquids sprayed by the plurality of lower nozzles 180.

Referring to FIGS. 2 and 3C, the plurality of lower nozzles 180 may be symmetrical to each other in the first horizontal direction X and the second horizontal direction Y about the spin chuck SC. Accordingly, the spray points on the rear surface 120b of the wafer 120, at which the temperature control liquids are sprayed from the plurality of lower nozzles 180, may also be symmetrical to each other in the first horizontal direction X and the second horizontal direction Y about the spin chuck SC. For example, there may be provided the plurality of lower nozzles symmetrical to each other in the first horizontal direction X about the spin chuck SC and the plurality of lower nozzles symmetrical to each other in the second horizontal direction Y about the spin chuck SC. In this case, as illustrated in FIG. 3C, a spray point 182b by the first lower nozzle 182, a spray point 184b by the second lower nozzle 184, and a spray point 186b by the third lower nozzle 186 may be arranged on the rear surface 120b of the wafer 120.

Accordingly, the temperature of the central region of the wafer 120 may be controlled by the heat transfer structure 150 that receives heat from the thermoelectric element 168, and the temperature of the outer region of the wafer 120 may be controlled by the temperature control liquids sprayed from the plurality of lower nozzles 180.

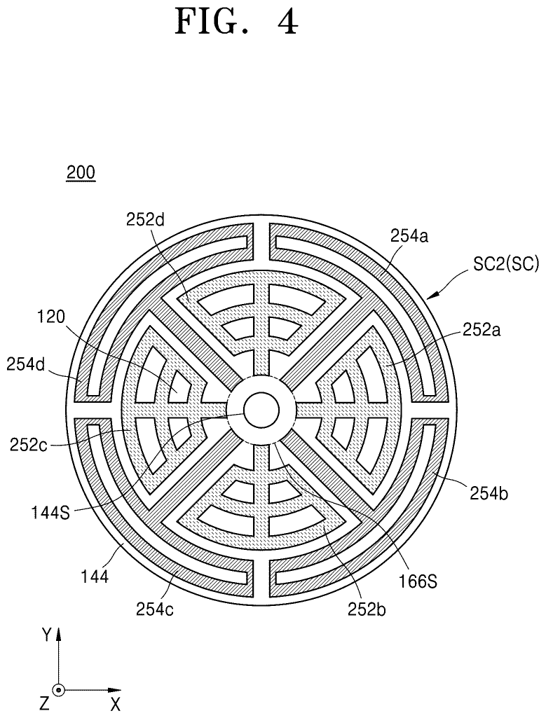

FIG. 4 is a layout showing an example wafer cleaning device 200. The wafer cleaning device 200 is generally similar to the wafer cleaning device 100 described with reference to FIGS. 2, 3A, 3B, and 3C, and thus, the following description focuses on the differences between the wafer cleaning device 100 and the wafer cleaning device 200.

Referring to FIG. 4, the heat transfer structure 150 of FIG. 2 may include a plurality of inner heat transfer structures 252a, 252b, 252c, and 252d (or referred to as first to fourth inner heat transfer structures 252a, 252b, 252c, and 252d) and a plurality of outer heat transfer structures 254a, 254b, 254c, and 254d (or referred to as first to fourth outer heat transfer structures 254a, 254b, 254c, and 254d). The plurality of inner heat transfer structures 252a, 252b, 252c, and 252d and the plurality of outer heat transfer structures 254a, 254b, 254c, and 254d may be spaced apart from each other. For example, the first inner heat transfer structure 252a, the second inner heat transfer structure 252b, the third inner heat transfer structure 252c, and the fourth inner heat transfer structure 252d may be arranged along the inner wall 166S of the lower plate 166 and spaced apart from each other with portions of the support upper plate 144 therebetween. The first outer heat transfer structure 254a, the second outer heat transfer structure 254b, the third outer heat transfer structure 254c, and the fourth outer heat transfer structure 254d may be arranged along the inner wall 166S of the lower plate 166 and spaced apart from each other with portions of the support upper plate 144 therebetween. The portions of the support upper plate 144 may be spaced apart from each other and respectively arranged between the first inner heat transfer structure 252a and the first outer heat transfer structure 254a, between the second inner heat transfer structure 252b and the second outer heat transfer structure 254b, between the third inner heat transfer structure 252c and the third outer heat transfer structure 254c, and between the fourth inner heat transfer structure 252d and the fourth outer heat transfer structure 254d.

Accordingly, a plurality of inner heat transfer structures 252 and a plurality of outer heat transfer structures 254 may independently heat the central region of the wafer 120. The plurality of inner heat transfer structures 252 and the plurality of outer heat transfer structures 254 may heat the central region of the wafer 120 at different target temperatures which are output from the wafer temperature regulator 40 shown in FIG. 1.

The plurality of inner heat transfer structures 252 and the plurality of outer heat transfer structures 254 may each include a plurality of arc-shaped pipes and a plurality of straight pipes. For example, the plurality of inner heat transfer structures 252 may each include three arc-shaped pipes, a straight pipe connecting ends of the three arc-shaped pipes to each other, another straight pipe connecting the other ends opposite to the ends of the three arc-shaped pipes, and another straight pipe connecting the central regions of three arc-shaped pipes. For example, the plurality of outer heat transfer structures 254 may each include two arc-shaped pipes, a straight pipe connecting ends of the arc-shaped pipes to each other, and another straight pipe connecting the other ends opposite to the ends of the arc-shaped pipes. The plurality of outer heat transfer structures 254 may each further include another straight pipe extending between the plurality of inner heat transfer structures 252.

As illustrated in FIG. 4, the heat transfer structure 150 of FIG. 2 may be provided in plurality, and the plurality of heat transfer structures 150 may independently heat the central region of the wafer 120. The number of heat transfer structures 150 is not limited to that shown in the drawing, and one or more heat transfer structures may be provided. In addition, the layout of the heat transfer structure 150 is not limited to that shown in the drawing, and various layouts may be provided.

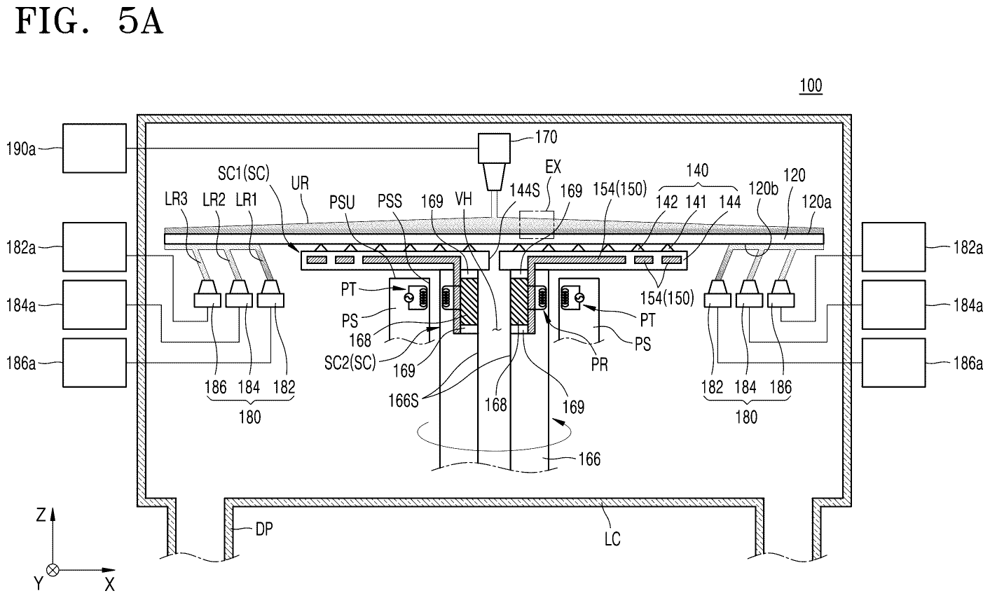

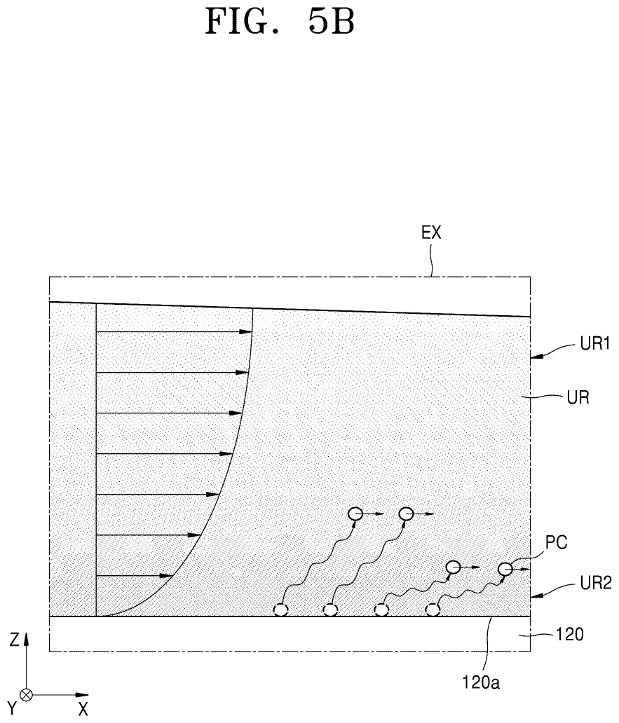

FIG. 5A is a cross-sectional view showing an operation process of the wafer cleaning device 100.

FIG. 5B is an enlarged view of FIG. 5A.

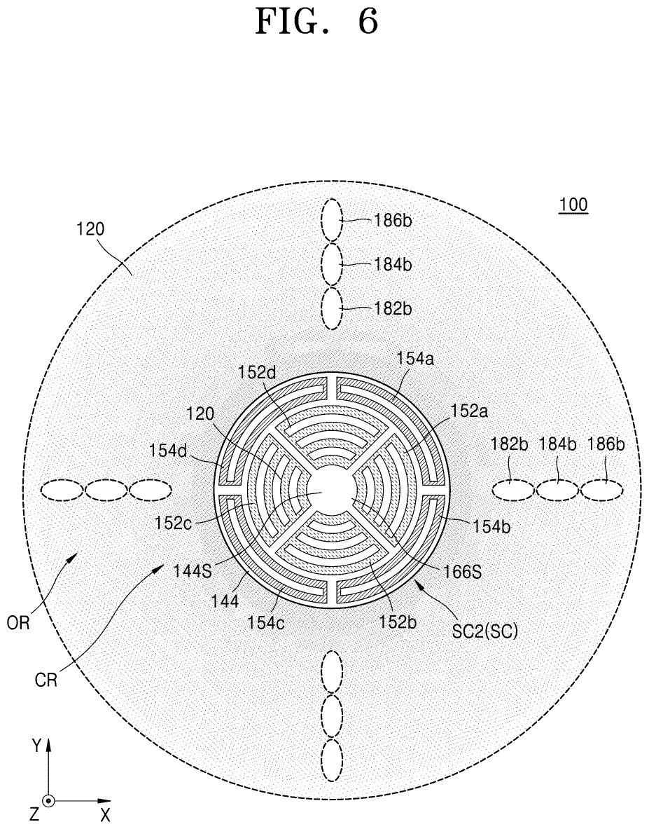

FIG. 6 is a layout showing the operation process of the wafer cleaning device 100.

As illustrated in FIGS. 5A and 5B, a cleaning solution may be sprayed from the upper nozzle 170 on the front surface 120a of the wafer 120 placed in the wafer cleaning device 100 to thereby form a cleaning solution layer UR. Also, a temperature control liquid may be sprayed from the plurality of lower nozzles 180 on the rear surface 120b of the wafer 120 to thereby form lower liquid layers LR1, LR2, and LR3 (or referred to as first to third lower liquid layers LR1, LR2, and LR3). The plurality of lower nozzles 180 may have different spray points on the rear surface 120b of the wafer 120, and thus, the plurality of lower liquid layers LR1, LR2, and LR3 may be formed.

The heat generated by the thermoelectric element 168 located inside the spin chuck SC may be transferred to the central region of the wafer 120 via the heat transfer structure 150, and the central region of the wafer 120 may be heated by the heat that is generated by the thermoelectric element 168. The temperature control liquid sprayed from the plurality of lower nozzles 180 may have a higher temperature than the wafer 120, and thus, the outer region of the wafer 120 may be heated by each of the lower liquid layers LR1, LR2, and LR3 that are formed by the temperature control liquid sprayed from the plurality of lower nozzles 180.

As the central region of the wafer 120 and the outer region of the wafer 120 are heated, the cleaning solution layer UR on the front surface 120a of the wafer 120 may be heated. The central region of the wafer 120 and the outer region of the wafer 120 that are connected to (e.g. in contact with) the cleaning solution layer UR are heated below the cleaning solution layer UR, and thus, the temperature gradient may be formed such that the temperature of a lower region UR2 of the cleaning solution layer UR is higher than an upper region UR1 of the cleaning solution layer UR.

Due to the temperature gradient of the cleaning solution layer UR, a thermophoresis effect may occur. In this specification, the thermophoresis effect refers to a phenomenon in which flow occurs from a high temperature region having high kinetic energy to a low temperature region having low kinetic energy. The lower region UR2 of the cleaning solution layer UR has a higher temperature than the upper region UR1 of the cleaning solution layer UR, and thus, the fluid forming the cleaning solution layer UR may move from the lower region UR2 of the cleaning solution layer UR to the upper region UR1 of the cleaning solution layer UR.

In addition, Marangoni convection may be generated due to the surface tension gradient that is generated by the temperature gradient between the upper region UR1 of the cleaning solution layer UR and the lower region UR2 of the cleaning solution layer UR. In this specification, the Marangoni convection refers to a phenomenon in which flow occurs from a region having low surface tension to a region having high surface tension due to the surface tension gradient. Since the surface tension decreases at high temperatures and increases at low temperatures, flow may occur from a high temperature region to a low temperature region. Marangoni convection is distinguished from Rayleigh-Benard convection in which buoyancy flow occurs from a high temperature region to a low temperature region due to a density gradient caused by a temperature difference in a reaction solution.

In the fluid that forms the cleaning solution layer UR, the temperature of the lower region UR2 of the cleaning solution layer UR is higher than the temperature of the upper region UR1 of the cleaning solution layer UR. Accordingly, the surface tension of the lower region UR2 of the cleaning solution layer UR may be lower than the surface tension of the upper region UR1 of the cleaning solution layer UR. Therefore, Marangoni convection may be generated from the lower region UR2 of the cleaning solution layer UR, having relatively low surface tension, toward the upper region UR1 of the cleaning solution layer UR, having relatively high surface tension.

Due to Marangoni convection, the fluid that forms the cleaning solution layer UR may move from the lower region UR2 of the cleaning solution layer UR to the upper region UR1 of the cleaning solution layer UR.

As illustrated in FIG. 5B, the fluid forming the cleaning solution layer UR moves from the lower region UR2 of the cleaning solution layer UR to the upper region UR1 of the cleaning solution layer UR by the thermophoresis effect and also by Marangoni convection. Accordingly, particles PC existing in the lower region UR2 of the cleaning solution layer UR may move to the upper region UR1 of the cleaning solution layer UR.

The cleaning solution layer UR is formed on the wafer 120 that is rotated by the spin chuck SC, and thus, centrifugal force may act on the cleaning solution layer UR. Accordingly, the cleaning solution layer UR may flow in the direction in which the wafer 120 rotates. The flow velocity of the cleaning solution layer UR may follow Equation 1 below.

$$u \approx U ( 2 \frac{z}{δ} - 2 \frac{{z}^{3}}{{δ}^{3}} + \frac{{z}^{4}}{{δ}^{4}} ) for z \leq δ \qquad [ Equation 1 ]$$

In Equation 1 above, u represents the flow velocity according to the height of the fluid in the cleaning solution layer (z), U represents the flow velocity of the upper region of the cleaning solution layer, δ represents the thickness of a section in which the flow velocity profile exists, and z represents the height in the flow velocity profile.

According to Equation 1 above, the flow velocity may increase as the height of the fluid in the cleaning solution layer increases. That is, as illustrated in FIG. 5B, the flow velocity applied to the particles PC may decrease in a direction toward the front surface 120a of the wafer 120 and the flow velocity applied to the particles PC may increase in a direction away from the front surface 120a of the wafer 120.

The force applied to the particles PC by the flow of the cleaning solution layer UR may follow Equation 2 below.

$${F}_{D , j} = 3 πμ {D}_{p} ( {u}_{j} - {v}_{j} ) \qquad [ Equation 2 ]$$

In Equation 2 above, F_{D,j} represents the force applied to the particles PC, μ represents the dynamic viscosity of the cleaning solution layer UR, Dₚ represents the size of the particles in the cleaning solution layer UR, uⱼ represents the flow speed of the cleaning solution layer UR, and vⱼ represents the speed of the particles PC.

According to Equation 2 above, the flow velocity applied to the particles PC decreases in the direction toward the front surface 120a of the wafer 120, and thus, the force applied to the particles PC may be reduced. Also, the flow velocity applied to the particles PC increases in the direction away from the front surface 120a of the wafer 120, and thus, the force applied to the particles PC may increase.

Due to the thermophoresis effect and Marangoni convection, the fluid forming the cleaning solution layer UR may move the particles PC existing in the lower region UR2 of the cleaning solution layer UR to the upper region UR1 of the cleaning solution layer UR. Accordingly, the particles PC may move away from the front surface 120a of the wafer 120, and the flow velocity applied to the particles PC may increase. Also, the force applied to the particles PC may increase due to the flow of the cleaning solution layer UR. Therefore, a cleaning effect may be improved when the temperature gradient is formed between the upper region UR1 and the lower region UR2 of the cleaning solution layer UR, compared to when the temperature gradient is not formed.

As illustrated in FIGS. 5A and 6, the cleaning solution layer UR including the cleaning solution sprayed from the upper nozzle 170 may be formed on the front surface 120a of the wafer 120 in the wafer cleaning device 100.

The heat generated by the thermoelectric element 168 located inside the spin chuck SC may be transferred to the central region of the wafer 120 via the heat transfer structure 150, and the central region of the wafer 120 may be heated by the heat that is generated by the thermoelectric element 168. The outer region of the wafer 120 may be heated by each of the lower liquid layers LR1, LR2, and LR3, which are formed by the temperature control liquid sprayed from the plurality of lower nozzles 180. Here, the heat transfer structure 150 has a higher temperature than each of the lower liquid layers LR1, LR2, and LR3 so that the central region of the wafer 120 has a higher temperature than the outer region of the wafer 120.

The temperature control liquid sprayed from the plurality of lower nozzles 180 may be sprayed toward different spray points. For example, as illustrated in FIG. 6, the first lower nozzle 182 may spray a temperature control liquid toward a first spray point 182b, the second lower nozzle 184 may spray a temperature control liquid toward a second spray point 184b, and the third lower nozzle 186 may spray a temperature control liquid toward a third spray point 186b.

The plurality of lower nozzles 180 may spray temperature control liquids having different temperatures. In implementations, the plurality of lower nozzles 180 may spray the temperature control liquids having the temperatures that decrease in the direction away from the spin chuck SC and increase in the direction toward the spin chuck SC. For example, the first lower nozzle 182 may spray a temperature control liquid having a first temperature toward the first spray point 182b, the second lower nozzle 184 may spray the temperature control liquid having a second temperature toward the second spray point 184b, and the third lower nozzle 186 may spray the temperature control liquid having a third temperature toward the third spray point 186b. The second temperature may be lower than the first temperature, and the third temperature may be lower than the second temperature. Therefore, the temperature of the second lower liquid layer LR2 may be lower than that of the first lower liquid layer LR1, and the temperature of the third lower liquid layer LR3 may be lower than that of the second lower liquid layer LR2.

As the central region of the wafer 120 and the outer region of the wafer 120 are heated, the cleaning solution layer UR sprayed on the front surface 120a of the wafer 120 may be heated. The heat transfer structure 150 has a higher temperature than each of the lower liquid layers LR1, LR2, and LR3, and the lower liquid layers LR1, LR2, and LR3 have temperatures that decrease in the direction away from the spin chuck SC. Accordingly, the temperature of the central region of the wafer 120 may be higher than the temperature of the outer region of the wafer 120. Also, the temperature gradient may be formed such that the temperature of a central region CR of the cleaning solution layer UR is higher than the temperature of an outer region OR of the cleaning solution layer UR.

The thermophoresis effect may be generated by the temperature gradient of the cleaning solution layer UR. The temperature of the central region CR of the cleaning solution layer UR is higher than the temperature of the outer region OR of the cleaning solution layer UR, and thus, the fluid forming the cleaning solution layer UR may move from the central region CR of the cleaning solution layer UR to the outer region OR of the cleaning solution layer UR.

In addition, Marangoni convection may be generated due to the surface tension gradient that is generated by the temperature gradient between the central region CR of the cleaning solution layer UR and the outer region OR of the cleaning solution layer UR.

In the fluid that forms the cleaning solution layer UR, the temperature of the central region CR of the cleaning solution layer UR is higher than the temperature of the outer region OR of the cleaning solution layer UR. Accordingly, the surface tension of the central region CR of the cleaning solution layer UR may be lower than the surface tension of the outer region OR of the cleaning solution layer UR. Therefore, Marangoni convection may be generated from the central region CR of the cleaning solution layer UR, having relatively low surface tension, toward the outer region OR of the cleaning solution layer UR, having relatively high surface tension.

Due to Marangoni convection, the fluid that forms the cleaning solution layer UR may move from the central region CR of the cleaning solution layer UR to the outer region OR of the cleaning solution layer UR.

The fluid forming the cleaning solution layer UR is moved, by the thermophoresis effect and Marangoni convection, from the central region CR of the cleaning solution layer UR to the outer region OR of the cleaning solution layer UR. Accordingly, the particles PC existing in the central region CR of the cleaning solution layer UR may move to the outer region OR of the cleaning solution layer UR.

The particles PC on the wafer 120 may be more easily removed to the outside when a temperature gradient is formed between the central region CR and the outer region OR of the cleaning solution layer UR, compared to when the temperature gradient is not formed.

Also, it may take a relatively short time to form the temperature gradient in the cleaning solution layer UR. For example, it may be assumed that the specific heat of the wafer 120 is 1630.3 KJ/m³K, the specific heat of DI water used as the cleaning solution is 4184 KJ/m³K, the heat flux of the wafer 120 is 753.7 W/m², the heat flux of DI water used as the cleaning solution is 3041.2 W/m², the wafer 120 has a temperature of 23 degrees Celsius (296.15 K), the heat transfer structure 150 of the spin chuck SC has a temperature of 28 degrees Celsius (301.15 K), the cleaning solution sprayed from the upper nozzle 170 has a temperature of 23 degrees Celsius (296.15 K), and the cleaning solution sprayed from the plurality of lower nozzles 180 has a temperature of 28 degrees Celsius (301.15 K).

When the cleaning solution layer UR has a height of 0.1 millimeters from the front surface 120a of the wafer 120 in the vertical direction Z and the wafer 120 has a height of 0.75 millimeters in the vertical direction Z, the heat capacity of the wafer 120 may be 86 J/K and the heat transfer rate of the wafer 120 may be 53.3 J/sec, and the heat capacity of the cleaning solution layer UR may be 295 J/K and the heat transfer rate of the cleaning solution layer UR may be 215.0 J/sec. In this case, it may take about 1.5 seconds to about 1.7 seconds to increase the temperature of the wafer 120 by 1 K. It may take about 1.3 seconds to about 1.5 seconds to increase the temperature of the cleaning solution layer UR by 1 K. Even when the wafer 120 has a height of 0.75 millimeters and the cleaning solution layer UR has a height of 0.1 millimeters, it takes about 2.8 seconds to about 3.2 seconds to increase the temperature of the wafer 120 and the temperature of the cleaning solution layer UR by 1 K. Accordingly, when the cleaning solution layer UR has a height from about 0.01 millimeters to about 0.03 millimeters, it may take a shorter time than the above-mentioned range. Therefore, cleaning efficiency may be maximized within a relatively short cleaning time due to the temperature gradient of the cleaning solution layer UR, and thus, productivity may be improved.

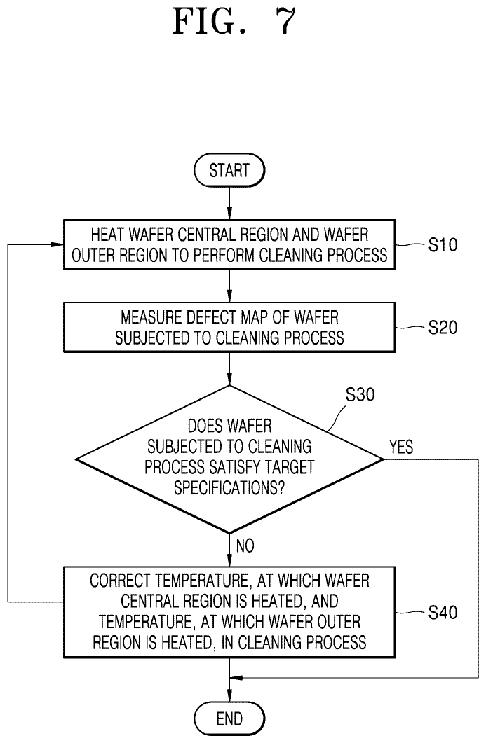

FIG. 7 is a diagram showing a heating temperature optimization process of the wafer cleaning device.

Referring to FIG. 7, first, a cleaning process may be performed by heating a wafer central region and a wafer outer region (S10). The wafer central region and the wafer outer region may be heated to different temperatures.

As described above, the wafer central region may include a plurality of heat transfer structures, and the plurality of heat transfer structures may be heated independently. Accordingly, the central region of the wafer may be heated to different target temperatures in a plurality of regions overlapping with the plurality of heat transfer structures. In addition, as described above, the wafer outer region is heated by the temperature control liquids sprayed from the plurality of lower nozzles, and the plurality of lower nozzles may spray the temperature control liquids independently. Accordingly, the outer region of the wafer may be heated to different target temperatures at a plurality of spray points of the plurality of lower nozzles.

Therefore, when the cleaning process is performed while heating the wafer central region and the wafer outer region, a plurality of regions, overlapping with the plurality of heat transfer structures, in the wafer central region and a plurality of regions, overlapping with the plurality of lower nozzles, in the wafer outer region may be heated to the plurality of target temperature values that are equal to or different from each other.

Subsequently, a defect map of the wafer subjected to the cleaning process may be measured (S20). In this specification, the defect map may refer to a map used to visualize defects on the wafer. By measuring the defect map of the wafer, it may be determined whether the wafer subjected to the cleaning process satisfies the target specifications (S30). If the wafer subjected to the cleaning process satisfies the target specifications (YES), the cleaning process may be completed. If the wafer subjected to the cleaning process does not satisfy the target specifications (NO), the target temperature of the wafer central region and the target temperature of the wafer outer region in the cleaning process may be corrected (S40).

Specifically, the plurality of target temperature values, which have been set in the previous operation (S10) of performing the cleaning process by heating the wafer central region and the wafer outer region, may be modified to a plurality of corrected target temperature values. Subsequently, the cleaning process may be performed again while a plurality of regions, overlapping with the plurality of heat transfer structures, in the wafer central region and a plurality of regions, overlapping with the plurality of lower nozzles, in the wafer outer region are heated to the plurality of corrected target temperature values.

Therefore, the heating of the wafer to the target temperature to perform the cleaning process, the measuring of the defect map of the wafer subjected to the cleaning process, the verifying whether the wafer satisfies the target specifications, and the heating of the wafer to the corrected target temperature to perform the cleaning process may be performed repeatedly. Accordingly, the optimized target temperature may be obtained so as to satisfy the target specifications of the wafer, and the cleaning process may be performed at the optimized target temperature.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A wafer cleaning device comprising:
an upper nozzle configured to spray a cleaning solution onto a front surface of a wafer;
a spin chuck provided below the wafer and configured to rotate the wafer and heat a central region of the wafer; and
a plurality of lower nozzles provided below the wafer and configured to spray, onto a rear surface of the wafer, a temperature control liquid having a higher temperature than the cleaning solution,
wherein the plurality of lower nozzles is configured to heat an outer region of the wafer that surrounds the central region of the wafer,
wherein a temperature gradient is defined by the spin chuck and the plurality of lower nozzles and causes the cleaning solution to flow in a cleaning solution layer on the front surface of the wafer.

2. The wafer cleaning device of claim 1, wherein the spin chuck comprises:
a power receiver configured to receive power;
a thermoelectric element configured to convert the power received from the power receiver into heat; and
a heat transfer structure configured to transfer the heat generated from the thermoelectric element to the central region of the wafer.

3. The wafer cleaning device of claim 1, wherein the plurality of lower nozzles are configured to spray temperature control liquids having different temperatures.

4. The wafer cleaning device of claim 1, wherein a lower nozzle closer to the central region of the wafer among the plurality of lower nozzles is configured to spray a temperature control liquid having a higher temperature than a temperature control liquid sprayed by a lower nozzle away from the central region of the wafer among the plurality of lower nozzles.

5. The wafer cleaning device of claim 1, wherein the spin chuck comprises:
an upper plate configured to fix the wafer in a horizontal direction and having a disc shape; and
a lower plate disposed below the upper plate and having a cylindrical shape,
wherein each of the upper plate and the lower plate comprises a vacuum hole that maintains a gap between the wafer and the upper plate in a vacuum state.

6. The wafer cleaning device of claim 5, wherein the lower plate comprises:
a thermoelectric element;
a heat transfer structure connected to an outer wall of the thermoelectric element; and
a heat insulating member configured to cover an upper surface and a lower surface of the thermoelectric element,
wherein an inner wall of the thermoelectric element is exposed via the vacuum hole.

7. The wafer cleaning device of claim 1, wherein the temperature gradient is defined such that a temperature of a lower region of the cleaning solution layer is higher than a temperature of an upper region of the cleaning solution layer, and
wherein flow of the cleaning solution layer is defined by a thermophoresis effect and by Marangoni convection generated by the temperature gradient.

8. The wafer cleaning device of claim 1, wherein the temperature gradient is defined such that a temperature of a central region of the cleaning solution layer is higher than a temperature of an outer region of the cleaning solution layer, and
wherein flow of the cleaning solution layer is defined by a thermophoresis effect and by Marangoni convection generated by the temperature gradient.

9. The wafer cleaning device of claim 1, wherein the spin chuck is configured to heat the central region of the wafer to a higher temperature than a temperature of a temperature control liquid of each of the plurality of lower nozzles.

10. The wafer cleaning device of claim 1, wherein the plurality of lower nozzles surrounds the spin chuck and are symmetrical to each other about the spin chuck.

11. A wafer cleaning device comprising:
an upper nozzle configured to spray a cleaning solution onto a front surface of a wafer;
a spin chuck provided below the wafer to rotate the wafer and configured to heat a central region of the wafer;
a plurality of lower nozzles provided below the wafer configured to spray a temperature control liquid onto a rear surface of the wafer and configured to heat an outer region of the wafer; and
a power transmission structure provided below the wafer, spaced apart from the spin chuck, and surrounding the spin chuck,
wherein the power transmission structure comprises a plurality of power transmitters that wirelessly transmit power, and
the spin chuck comprises:
a plurality of power receivers configured to wirelessly receive the power from the plurality of power transmitters;
a plurality of thermoelectric elements configured to convert the power received from the plurality of power receivers into heat; and
a plurality of heat transfer structures configured to transfer the heat generated by the plurality of thermoelectric elements to the central region of the wafer, the heat transfer structures heating the central region of the wafer to different temperatures,
wherein the spin chuck and the plurality of lower nozzles cause the cleaning solution sprayed from the upper nozzle to flow in a cleaning solution layer on the front surface of the wafer.

12. The wafer cleaning device of claim 11, wherein the plurality of power transmitters respectively transmit a different power to each of the plurality of power receivers.

13. The wafer cleaning device of claim 11, wherein each of the plurality of heat transfer structures comprises a heat pipe.

14. The wafer cleaning device of claim 11, wherein the spin chuck further comprises a heat insulating member, and
the plurality of thermoelectric elements are spaced apart from each other with the heat insulating member therebetween.

15. The wafer cleaning device of claim 11, wherein the plurality of heat transfer structures have a higher temperature than the temperature control liquid sprayed from the plurality of lower nozzles.

16. A wafer cleaning device comprising:
a cleaning chamber;
a spin chuck located in a lower portion of the cleaning chamber;
an upper nozzle disposed in an upper portion of the cleaning chamber and configured to spray a cleaning solution;
a power transmission structure spaced apart from the spin chuck and surrounding the spin chuck; and
a plurality of lower nozzles spaced apart from the power transmission structure and configured to spray a temperature control liquid,
wherein the power transmission structure comprises a power transmitter that transmits power, and
the spin chuck comprises:
a power receiver configured to receive the power from the power transmitter;
a thermoelectric element configured to convert the power received from the power receiver into heat;
a heat transfer structure connected to the thermoelectric element and configured to transfer the heat generated from the thermoelectric element; and
a vacuum hole,
wherein the spin chuck and the plurality of lower nozzles are configured to generate at least one of a thermophoresis effect or Marangoni convection.

17. The wafer cleaning device of claim 16, wherein the plurality of lower nozzles spray temperature control liquids having different temperatures.

18. The wafer cleaning device of claim 16, wherein the thermoelectric element is provided in plurality, and
the plurality of thermoelectric elements are each heated to a different temperature.

19. The wafer cleaning device of claim 16, wherein each of the power transmitter and the power receiver comprises an electromagnetic coil panel, and
the power receiver faces the power transmitter and receives the power wirelessly from the power transmitter.

20. The wafer cleaning device of claim 16, wherein the spin chuck comprises:
an upper plate configured to fix the wafer in a horizontal direction and having a disc shape; and
a lower plate disposed below the upper plate and having a cylindrical shape,
wherein the upper plate comprises:
a support upper plate extending lengthwise in the horizontal direction; and
a plurality of inner pins and outer pins protruding in a vertical direction from the support upper plate.
